(19) United States
(12) Patent Application Publication
(10) Pub. No.: US 2026/0238203 A1
(43) Pub. Date: Aug. 13, 2026

(54) Device with a Differential Output Stage

(71) Applicant: TDK-Micronas GmbH, Freiburg im Breisgau (DE)

(72) Inventors: Nils Remmers, Schopfheim (DE); David Muthers, Denzlingen (DE)

(21) Appl. No.: 19/534,976

(22) Filed: Feb. 10, 2026

(30) Foreign Application Priority Data
Feb. 11, 2025 (DE) 102025104897.5

(51) Int. Cl. H03K 17/16; G05F 3/20; G05F 3/24; G05F 3/26; G05F 3/30

(52) U.S. Cl. CPC H03K 17/162; G05F 3/205; G05F 3/24; G05F 3/262; G05F 3/30

(57) ABSTRACT

A device has a differential output stage that has a first and a second complementary half bridge, in each of which two transistors are connected in series. A section of the half bridge located, in each case, between the transistors of each half bridge, is connected, in each case, to a signal output for a partial signal of a differential voltage signal. The device has a fault detection circuit to detect a fault on a load connected to the signal outputs. A transistor of each half bridge, in each case, is part of a current mirror, each of which is designed and coupled with a driver assigned to this transistor, such that when an output current flows in the applicable half bridge, a test current proportional to this output current flows in a current path assigned to this half bridge. The current path are connected to a summation node to add the test currents. The summation node is connected to a comparator in order to compare the sum current of the test currents with a reference value or a reference value range.

### CROSS-REFERENCE TO RELATED APPLICATION

This application claims priority to German Patent Application No. 102025104897.5 filed Feb. 11, 2025, the disclosure of which is hereby incorporated by reference in its entirety.

### BACKGROUND OF THE INVENTION

### Field of the Invention

The invention relates to a device with a differential output stage, which has a first and a second half bridge, in which respectively a first transistor and a second transistor are connected in series, where the transistors each have a control input that is connected to a driver assigned respectively to this,
where a section of the first half bridge located between the transistors of the first half bridge is connected to a first signal output for a first partial signal of a differential voltage signal, and
where a section of the second half bridge located between the transistors of the second half bridge is connected to a second signal output for a second partial signal of the differential voltage signal,
   and with a fault detection circuit to detect a fault on a load that is connected or can be connected to the signal outputs.

### Description of Related Art

Sensor technology is gaining in importance in the automotive engineering sector. In particular, when sensor technology is used in safety applications, there are very high requirements not only in terms of precision but also in terms of sensor signal reliability. In accordance with the state of the art, redundant design, including system plausibility checks, increases system reliability.

As an alternative to redundancy, relevant signal paths in the systems are monitored or in terms of known sources of interference or effects are designed to be fault resilient through compensating architecture.

Particularly in the area of electronic circuit architecture in conjunction with physical sensors many approaches that lead to robust systems are known. A generic example of this is the temperature compensation of circuit and sensor intrinsic in modern sensor systems. And other effects, such as those associated with electromagnetic compatibility (EMC), are already partially compensated for with satisfactory results.

The prerequisite for good and reliable compensation is precise knowledge of the mechanisms of action with which the disturbances are entered into the sensor system. Among the less well specified mechanisms of action are faults in particular resulting from the failure or malfunction of components involved in the function of the overall system. In this case, disturbance compensation fails and reliability is ensured only through diagnostic instances that permanently monitor operation of the systems. A faulty output signal can no longer be prevented in this case, but it can, at a minimum, be detected and signaled to a higher system instance.

In the case of monolithic integrated sensor systems or integrated circuits (ICs) in general, external circuitry is also among the system components potentially causing faults, including the input periphery of an evaluation unit to which the data or sensor signals are transmitted.

In many application scenarios, the output signals of the output stage are present as differential or absolute output voltages. An output amplifier drives the external loads, which are comprised of ohmic, capacitive, and inductive components and are also partially of a parasitic type.

A differential signal output consists of two individual signal outputs that are measured differentially by an evaluation unit. In the literature, this procedure is also called symmetrical signal transmission. The advantage is that line-bound transmission is significantly more robust. In particular, interference of the type described, such as EMC, is almost fully suppressed by differential or symmetric transmission. The prerequisite for this is highest possible symmetric load conditions of the two individual signal outputs that as a pair form the differential output. With regard to the system as a whole, this requires that the source, line, and load impedances all have to be identical.

A violation of this symmetry under circumstances does not result directly in faulty transmission of a signal, which in practice, for example, represents a measurement value, but rather results in a significant reduction in signal transmission robustness.

EP 3 018 830 A1 reveals a detection device to monitor the quality of a differential wire-bound communication connection. On the receiver side of the communication connection, a fault detection circuit monitors various parameters during signal transmission in both lines of the differential communication connection. Among others, the signal levels that occur are measured and assessed both as absolute and as differential. Furthermore, additional parameters, such as short circuit detection and slew rate detection, are performed in separate modules.

### SUMMARY OF THE INVENTION

The task of the invention is to create a device of the type mentioned above, which, on the output stage side, can detect a fault in an external load that is connected to or can be connected to the signal outputs, and/or a fault on lines that connect the load to the signal outputs.

The task is accomplished by a device as described herein. Advantageous embodiments of the invention are the subject of dependent claims.

According to the invention, for the device of the type mentioned above, it is provided
that a transistor of the first half bridge is part of a first current mirror that has a first current path, which is designed in such a manner and coupled to the driver assigned to this transistor, that when an output current in the first half bridge flows in the first current path, a first test current proportional to this output current flows,
that a transistor of the second half bridge is part of a second current mirror that has a second current path, which is designed in such a manner and coupled to the driver assigned to this transistor, that when an output current in the second half bridge flows in the second current path, a second test current proportional to this output current flows,
   that the first current path and the second current path are connected to a summation node to add the first and second first and second test current, and that the fault detection circuit has a comparator that is connected to the summation node to compare the sum current from the first and second test current with a reference value or a reference value range. In an advantageous manner, this device enables the detection of an asymmetry in the loads connected between the signal outputs. An asymmetry indicates a fault.

It is important here that the sum of the input currents of the current mirror flowing through the transistors arranged in the half bridges essentially remains constant as long as the loads connected to the signal outputs of the output stage are symmetrical. The sum current from the currents in the first and second current path is compared with a reference value or reference value range that preferably matches the expected value of the sum current. Because an asymmetry, stated differently a fault in the symmetry of the loads, would cause a deviation from the expected value of the sum current, fault detection can also take place through comparison of the reference value or reference value range with the sum current.

The output stage and the fault detection circuit, with the current mirrors and comparator, are preferably integrated in a semiconductor chip as an integrated circuit. The device then enables an IC internal detection of faults from the loads connected to the signal outputs. This enables a high degree of diagnostic coverage for the output amplifier and the housing of the integrated circuit.

Because the detection of faults can be performed on the signal source side or on the output stage side (this corresponds to a receiver of the transmission side for a wire-bound transmission of the differential voltage signal of the output stage), the effort and expenditure associated with the circuitry is reduced, which contributes to an increase in reliability. When used in automobiles, for example, in the area of functional safety according to ISO26262 (“Road vehicles—Functional safety”), this leads to an improvement in key data such as SPFM (single point fault metric) and PMHF (Probabilistic Metric for Random Hardware Failures).

Preferably, the first and second transistor of the first half bridge are designed complementary to one another and/or the first and second transistor of the second half bridge are designed complementary to one another.

Preferably, a first transistor element is arranged in the first current path, the control input of which is connected to the control input of the first transistor of the first half bridge, and/a second transistor element is arranged or in the second current path, the control input of which is connected to the control input of the first transistor of the second half bridge. This enables precise mirroring of the current flowing through the applicable half bridge in the first or second current path.

In an advantageous embodiment of the invention, the first transistor of the first half bridge and the first transistor of the second half bridge are each designed as a PMOS transistor. Here, the first transistor element and the second transistor element can also be designed as a PMOS transistor element. In the process, the control input (gate) of the first transistor element is preferably connected to the control input (gate) of the first transistor of the first half bridge and the control input (gate) of the second transistor element is preferably connected to the control input (gate) of the first transistor of the second half bridge. The device can thus be integrated easily into a semiconductor chip.

In an alternative embodiment of the invention, the first transistor of the first half bridge and the first transistor of the second half bridge are each designed as an NMOS transistor. In this design as well, the control input (gate) of the first transistor element is preferably connected to the control input (gate) of the first transistor of the first half bridge and the control input (gate) of the second transistor element is preferably connected to the control input (gate) of the first transistor of the second half bridge, where however the transistor elements are designed as NMOS transistors.

In a further development of the invention, the comparator for mirroring the sum current from the first and the second current path to a third current path has a third current mirror with a third transistor and a third transistor element, where the third transistor element is connected in series, in the third current path, to a reference current source, where the third transistor is arranged in a fourth current path, which connects the summation node to a supply voltage connector, and where the control input of the third transistor and the control input of the third transistor element are each connected to the summation mode. The comparison result between the reference current of the reference current source and the sum current from the first and second current path can then be obtained as electric voltage on a node in the third current path, arranged between the third transistor element and the reference current source and on the summation node.

If the transistors and transistor elements of the first and second current mirror are PMOS transistors, in a preferred embodiment of the invention the transistors of the third current mirror are NMOS transistors. The reference current source thus can have PMOS transistors.

In an alternative embodiment of the invention, the transistors and transistor elements of the first and second current mirror are NMOS transistors, and the transistors of the third current mirror are PMOS transistors.

### BRIEF DESCRIPTION OF THE DRAWINGS

Additional details, characteristics, and benefits of the invention can be determined from the following description of exemplary embodiments, taking into account the drawing.

It shows:

FIG. 1 A schematic representation of a device with a differential signal output to which loads are connected,

FIG. 2 A first exemplary embodiment of the device, and

FIG. 3 A second exemplary embodiment of the device.

### DESCRIPTION OF THE INVENTION

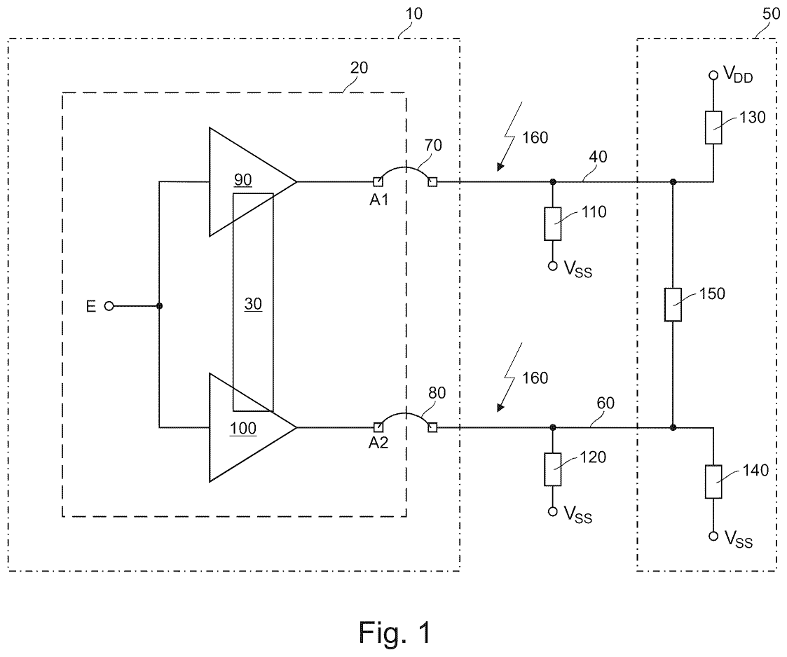

The illustration in FIG. 1 shows a schematic representation of a device 10 designed as an integrated circuit, which has a microchip 20 in which a differential output stage and a fault detection circuit 30 to detect faults on a load that is connected to differential signal outputs A1, A2 of the output stage.

A first signal output A1 of the device 10 is connected to a first connector of an evaluation unit 50 via a first line 40. A second signal output A2 of the device 10 is connected to a second connector of an evaluation unit 50 via a second line 60.

The first signal output A1 provided on the microchip 20 is connected to the first line 40 by means of a first bond connection 70, and the second output A2 provided on the microchip 20 is connected to the second line 60 by means of a second bond connection 80.

The first bond connection 70 is electrically connected to the output of a first amplifier 90 of the differential output stage. The second bond connection 80 is electrically connected to the output of a second amplifier 100 of the differential output stage.

The inputs of the first amplifier 90 and of the second amplifier 100 are connected to an input signal connector E. The first amplifier 90 and the second amplifier 100 generate a symmetrical, differential output signal from the input signal E. The evaluation unit 50 receives the output signal of the device 10 by means to two symmetrical differential inputs formed by the first line 40 and the second line 60.

The first line 40 has a first line impedance 110, and the second line 60 has a second line impedance 120. The evaluation unit has a first load impedance 130 on the first input, by way of which the first input is connected to a first supply voltage potential V_{DD}. At its second input, the evaluation unit has a second load impedance 140, by way of which the second input is connected to a second supply potential V_{SS}. In addition, the evaluation unit 50 has a differential load impedance 150 that operates between the first line 40 and the second line 60.

The line impedances 110 and 120 are also identical, in each instance, just like the load impedances 130 and 140. Through this completely symmetrical configuration and its differential readout by the evaluation unit 50, symmetrically acting interference 160 is fully suppressed. An asymmetry in the listed impedances 110, 120, 130, 140, and 150 would also control interference 160 asymmetrically in lines 40 and 60. As a result, the recorded interference 160 that is introduced would no longer be fully suppressed.

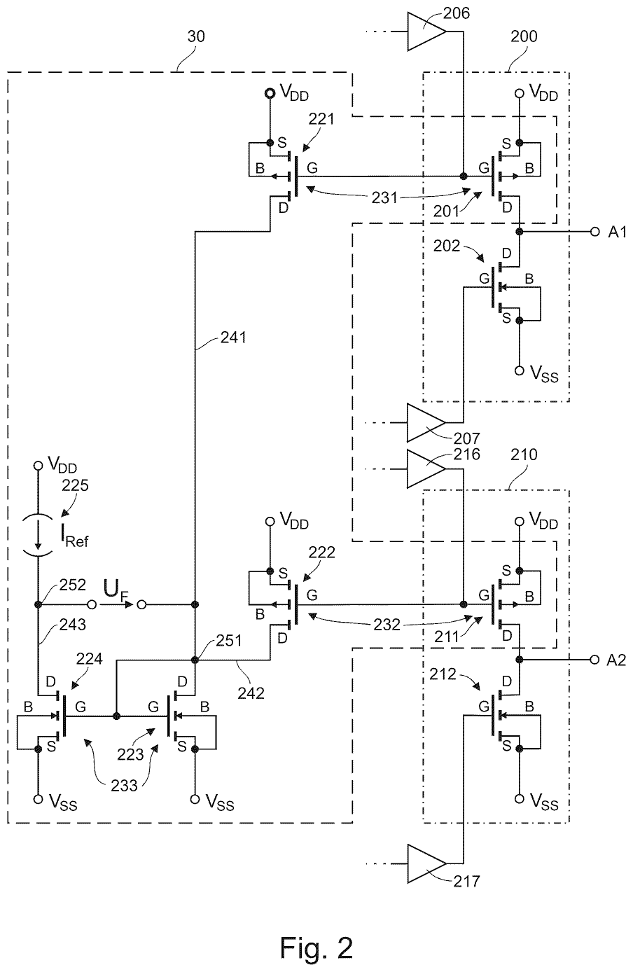

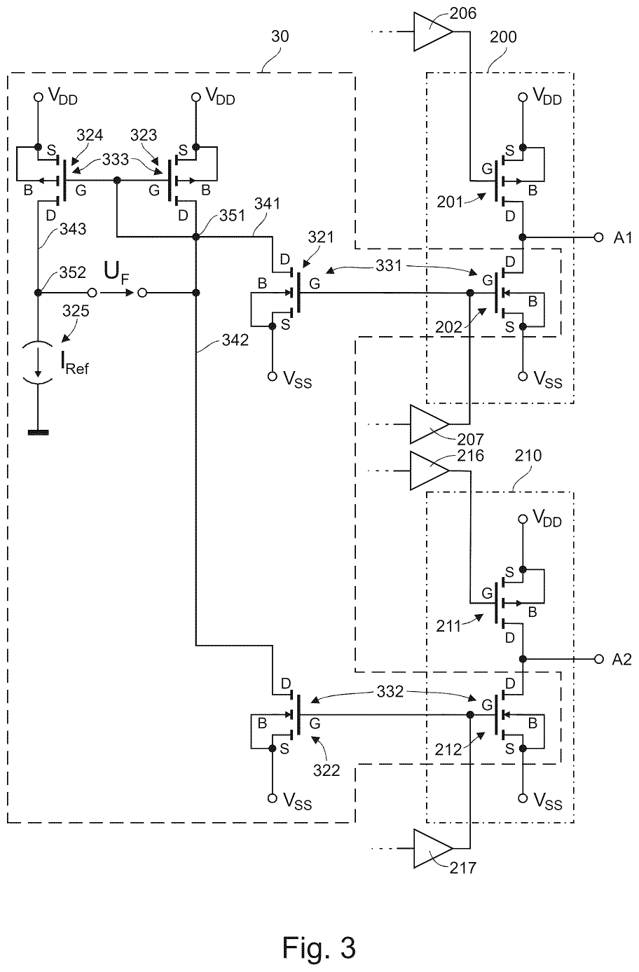

In the exemplary embodiment shown in FIGS. 2 and 3, the first amplifier 90 has a first complementary half bridge 200 or a first complementary line driver and the second amplifier 100 has a second complementary half bridge 210 or a second complementary line driver. Every half bridge 200, 201 each has a first transistor 201, 211 and a second transistor 202, 212 connected in series with it, which is designed to be complementary to the first transistor 201, 211. In the exemplary embodiments shown in the drawing, complementary means the series circuit of PMOS and NMOS transistors.

For the first half bridge 200, the source of the first transistor 201, designed as a PMOS transistor, is connected to the first supply potential V_{DD}, and the drain of the first transistor 201 is connected to the signal output A1 and the drain of the second transistor 202, which is designed as an NMOS transistor. The source of the second transistor 202 is connected to the second supply potential V_{SS}.

In a corresponding manner, for the second complementary half bridge 210 the source of the first transistor 211, designed as a PMOS transistor, is connected to the first supply potential V_{DD}, and the drain of the PMOS transistor 211 is connected to the signal output A2 and the drain of the second transistor 212, which is designed as an NMOS transistor. The source of the second transistor 212 is connected to the second supply potential V_{SS}.

Both the first transistors 201 and 211 and the second transistors 202 and 212 in the two half bridges 200 and 210 can each be designed as a group of multiple, identical individual transistors connected to one another in parallel.

The first transistor 201 of the first half bridge 200 is part of a first current mirror 231 that has a first current path 241. A first transistor element 221 designed as a PMOS transistor is arranged in the first current path 241, its control input or gate is connected to the control input or gate of the first transistor 201 of the first half bridge. In the exemplary embodiment shown in FIG. 2, the source of the first transistor element 221 is connected to the first supply voltage potential V_{DD}, and the drain of the first transistor element 221 is connected to a summation node 251.

To mirror the input current flowing through the source-drain stretch of the first transistor 201 of the first half bridge 200 in the first current path 241, the first signal output A1 is internally fed back, which in turn regulates the first current mirror 231. Since the control inputs or gates of the first transistor element 221 and of the first transistor 201 of the first half bridge 200 are actuated equally with regard to the same source potential V_{DD}, the Source-Drain current through the first transistor element 221 is proportional to the Source-Drain current through the first transistor 201 of the first half bridge 200 (assuming the same operating state). The current through the first transistor 201 therefore impacts the potential on the first signal output A1, and this acts on a control loop that regulates the gate potential on the first transistor element 221.

The first transistor 211 of the second half bridge 210 is part of a second current mirror 232 that has a second current path 242. A second transistor element 222 is arranged in the second current path 242; its control input or gate is connected to the control input or gate of the first transistor 211 of the second current mirror 232. The source of the second transistor element 222 is connected to the first supply voltage potential V_{DD}, and the drain of the second transistor element 222 is connected to the summation node 251.

To mirror the input current flowing through the source-drain stretch of the first transistor 211 of the second half bridge 210 in the second current path 242, the second signal output A2 is internally fed back, and this in turn regulates the second current mirror 232. Since the control inputs or gates of the first transistor element 221 and of the first transistor 211 of the second half bridge 210 are actuated equally with regard to the same source potential V_{DD}, the current through the second transistor element 221 is proportional to the current through the first transistor 211 of the second half bridge 210 (assuming the same operating state). The current through the first transistor 211 therefore impacts the potential on the second signal output A2, and this acts on a control loop that regulates the gate potential on the second transistor element 222.

The currents mirrored from the first and/or second transistor elements 221 and 222 in the first or second current path 241, 251, and referred to as test currents in the following are connected to the summation node 251 parallel to one another The summation node 251 is connected to the input of a third current mirror 233. To mirror the sum current from the first and the second current path 241, 242, the third current mirror 233 has a third transistor 223 and a third transistor element 224 in a third current path 243. The third transistor 223 and the third transistor element 224 are each designed as an NMOS transistor.

The third transistor element 224 is connected in series in a third current path 243 to a reference current source 225, which is connected with its first connector to the first supply voltage potential V_{DD}, and with its second connector, to a node that is connected to the drain of the third transistor element 224. A reference current I_{Ref} flows between the first and second connector of the reference current source 225.

The third transistor 223 is arranged in a fourth current path, which connects the summation node 251 to the second supply voltage connector V_{SS}. The control input of the third transistor 223 and the control input of the third transistor element 224 are connected to the summation node 251 and the drain of the third transistor 223. The source of the third transistor 223 lies on the second supply potential V_{SS}.

Instead of the third transistor 223, an ohmic load could also be provided, and the absolute voltage could be evaluated via the load.

A difference between the reference current I_{Ref} of reference current source 225 and the current sum of the test currents in the first current path 241 and second current path 242 is expressed in a voltage modulation on a voltage tap U_{F}. The voltage tap U_{F} has a first contact connected to the summation node 251 and a second contact connected to the node 252. If the current sum is identical to the reference current I_{Ref}, under ideal conditions (no noise) the voltage modulation on the voltage tap U_{F} equals 0 volts.

It should still be noted that the voltage on node 252 is not measured against the summation node 251, but instead can also be measured against the second supply voltage potential V_{SS} or another reference.

In the exemplary embodiment shown in FIG. 3, the half bridges 200 and 210 correspond to the half bridges 200 and 210 according to FIG. 2. Also, the drivers 206, 216, 207, 217 of FIG. 3 correspond to those of FIG. 2, which is why the description of FIG. 2 applies accordingly in this respect for FIG. 3.

In this exemplary embodiment, however, the second transistor 202 of the first half bridge 200 is part of a first current mirror 331 that has a first current path 341. In the first current path 341, a first transistor element 321 (NMOS) is arranged, whose control input or gate for mirroring the current flowing through the first half bridge 200 is connected to the control input or gate of the second transistor 202 of the first half bridge 200. The source of the first transistor element 321 is connected to the first supply potential V_{SS}, and the drain of the first transistor element 321 is connected to a summation node 351.

The second transistor 212 of the second half bridge 210 is part of a second current mirror 332 that has a second current path 342. In the second current path 342 a second transistor element 322 (NMOS) is arranged, whose control input or gate for mirroring the current flowing through the second half bridge 210 is connected to the gate of the second transistor 212 of the second half bridge 210. The source of the second transistor element 322 is connected to the second supply potential V_{SS}, and the drain of the second transistor element 322 is connected to a summation node 351. The currents mirrored by the transistor elements 321 and 322 are therefore connected parallel to one another at the summation node 351.

The summation node 351 is connected to the input of a third current mirror 333. To mirror the sum current from the first and the second current path 341, 342, in a third current path 343 the third current mirror 333 has a third transistor 323 and a third transistor element 324. The third transistor 323 and the third transistor element 324 are each designed as a PMOS transistor.

The third transistor element 324 is connected in series in a third current path 343 to a reference current source 325, which is connected with its first connector to the ground potential and with its second connector to a node 352 that is connected to the drain of the third transistor element 324. A reference current I_{Ref} flows between the first and second connector of the reference current source 325.

The third transistor 223 is arranged in a fourth current path, which connects the summation node 351 to the first supply voltage connector V_{DD}. The control input of the third transistor 323 and the control input of the third transistor element 324 are connected to the summation node 351 and the drain of the third transistor 323. The source of the third transistor 323 lies on the first supply potential V_{DD}.

A difference between the reference current I_{Ref} of reference current source 325 and the current sum of the test currents in the first current path 341 and second current path 342 is expressed in a voltage modulation at a voltage tap U_{F}. The voltage tap U_{F} has a first contact connected to the summation node 351, and a second contact connected to the node 352. If the current sum is identical to the reference current I_{Ref}, under ideal conditions (no noise) the voltage modulation on the voltage tap U_{F} equals 0 volts.

1. A device with a differential output stage, which has a first and a second half bridge, in which respectively a first transistor and a second transistor are connected in series, where the transistors each have a control input that is connected to a driver assigned respectively to it,
where a section of the first half bridge located between the transistors of the first half bridge is connected to a first signal output for a first partial signal of a differential voltage signal, and
where a section of the second half bridge located between the transistors of the second half bridge is connected to a second signal output for a second partial signal of the differential voltage signal,
and with a fault detection circuit to detect a fault, wherein
a transistor of the first half bridge is part of a first current mirror that has a first current path, which is designed and coupled to the driver assigned to this transistor, in such a manner that when an output current in the first transistor of the first half bridge flows in the first current path, a first test current proportional to this output current flows,
a transistor of the second half bridge is part of a second current mirror that has a second current path, which is designed and coupled to the driver assigned to this transistor, in such a manner that when an output current in the first transistor of second half bridge flows in the second current path, a second test current proportional to this output current flows,
the first current path and the second current path are connected to a summation node to add up the first and second test current, and that the fault detection circuit has a comparator that is connected to the summation node to compare the sum current from the first and second test current with a reference value or a reference value range.

2. The device according to claim 1, wherein the first and second transistor of the first half bridge are designed complementary to one another and/or that the first and second transistor of the second half bridge are designed complementary to one another.

3. The device according to claim 1, wherein a first transistor element is arranged in the first current path, the control input of which is connected to the control input of the first transistor of the first half bridge and/or a second transistor element is arranged in the second current path, the control input of which is connected to the control input of the first transistor of the second half bridge.

4. The device according to claim 1, wherein the first transistor of the first half bridge and the first transistor of the second half bridge are each designed as a PMOS transistor.

5. The device according to claim 4, wherein the first transistor element and the second transistor element are each designed as a PMOS transistor element.

6. The device according to claim 1, wherein the first transistor of the first half bridge and the first transistor of the second half bridge are each designed as an NMOS transistor.

7. The device according to claim 6, wherein the first transistor element and the second transistor element are each designed as an NMOS transistor element.

8. The device according to claim 1, wherein the comparator to mirror the sum current from the first and second current path has a third current mirror with a third transistor and a third transistor element in a third current path, that the third transistor element is connected is series in the third current path to a reference current source, that the third transistor is arranged in a fourth current path, which connects the summation nodes to a supply voltage connector, and that the control input of the third transistor and the control input of the third transistor element is each connected to the summation node.

9. The device according to claim 8, wherein the third transistor and the third transistor element are each designed as an NMOS transistor.

10. The device according to claim 8, wherein the third transistor and the third transistor element are each designed as a PMOS transistor.
